(19) United States
(12) Patent Application Publication
(10) Pub. No.: US 2015/0200315 A1
(43) Pub. Date: Jul. 16, 2015

(54) ELECTRONIC MODULE

(71) Applicant: FUJIFILM Corporation, Tokyo (JP)

(72) Inventor: Atsushi MUKAI, Ashigara-kami-gun (JP)

(73) Assignee: FUJIFILM CORPORATION, Tokyo (JP)

(21) Appl. No.: 14/671,176

(22) Filed: Mar. 27, 2015

Related U.S. Application Data
(63) Continuation of application No. PCT/JP2013/075863, filed on Sep. 25, 2013.

(30) Foreign Application Priority Data
Sep. 28, 2012 (JP) 2012-217689

(51) Int. Cl. H01L 31/0392; H01L 31/0749; H01L 31/048

(52) U.S. Cl. CPC H01L 31/03928; H01L 31/048; H01L 31/0749

(57) ABSTRACT

An electronic module is provided which includes an electronic device in which an electronic element is provided on a flexible substrate that does not transmit water vapor, an edge sealant provided at a peripheral edge of the flexible substrate of the electronic device, and a water vapor barrier film provided so as to cover a region surrounded by the edge sealant. When a square root of twice a diffusion coefficient of the edge sealant is denoted by K, K is not greater than 0.1 cm/√h. The water vapor barrier film includes a support member made of a transparent resin and at least one inorganic layer formed on the support member, and the support member is disposed on a side on which the edge sealant is located.

### CROSS-REFERENCE TO RELATED APPLICATIONS

This application is a Continuation of PCT International Application No. PCT/JP2013/075863 filed on Sep. 25, 2013, which claims priority under 35 U.S.C. §119(a) to Japanese Patent Application No. 2012-217689 filed on Sep. 28, 2012. Each of the above application(s) is hereby expressly incorporated by reference, in its entirety, into the present application.

### BACKGROUND OF THE INVENTION

The present invention relates to an electronic module in which electronic devices including organic EL (electroluminescence) elements, solar battery elements, or the like are modularized, and particularly relates to an electronic module capable of suppressing moisture ingress into the module and ensuring high reliability even when internal electronic devices are sensitive to moisture.

Conventionally, electronic devices such as solar battery cells have been modularized by being sealed with a resin and further providing with a water vapor barrier film and a backsheet for the purpose of preventing moisture and the like from ingressing into the devices. For example, in WO 2011/143205, FIG. 2 illustrates a flexible thin film solar battery in which a photovoltaic cell, a muti-layer backsheet, and a transparent barrier frontsheet are layered via an adhesive sealing layer.

Meanwhile, there is also a conventional electronic module 100 that is flexible, configured as illustrated in FIG. 6. In the electronic module 100, an electronic device 102 in which an electronic element 102a is formed on a flexible substrate 102b is completely covered by a filling material 104, and an edge sealant 106 is provided on the periphery of the filling material 104. A water vapor barrier film 108 is disposed on the side on which the electronic element 102a of the electronic device 102 is located, and an opaque backsheet 110 having barrier properties is disposed on the side on which the flexible substrate 102b is located.

The water vapor barrier film 108 includes a barrier layer 108b having an organic layer and an inorganic layer and formed on a transparent support member 108a made of PET or the like, and a water vapor transmission rate is decreased by the inorganic layer. Meanwhile, in the backsheet 110, a support member 110a made of PET or the like is laminated to an Al or SUS metal foil 110b that has a thickness of not less than 30 μm, and the water vapor transmission rate is decreased by the metal foil 110b.

A structure that includes a backsheet as in the flexible thin film solar battery disclosed in WO 2011/143205 and the electronic module 100 have problems such as those described hereinafter. Note that the flexible thin film solar battery disclosed in WO 2011/143205 and the electronic module 100 have similar configurations, and thus the electronic module 100 will be used as an example in the following descriptions.

In the electronic module 100, water vapor is thought to ingress through an ingress passage between a cross-section of the water vapor barrier film 108 and the backsheet 110 and a cross-section of the edge sealant 106. The support member 108a of the water vapor barrier film 108 and the support member 110a of the backsheet 110 are formed from a material, such as PET, whose water vapor transmission rate is approximately 5 g/m²/day. The edge sealant 106 is primarily formed of polyisobutylene, whose water vapor transmission rate is from 0.05 to 0.5 g/m²/day, and more preferably, contains a material containing a hygroscopic material. As such, water vapor ingressing from end portions of the film in the electronic module 100 primarily follows passages passing along the support member 108a of the water vapor barrier film 108 and the support member 110a of the backsheet 110.

In this manner, according to the electronic module 100, the support member 108a of the water vapor barrier film 108 and the support member 110a of the backsheet 110 serve as moisture ingress passages P (leakage paths), and there is a problem that a large amount of moisture ingresses into the electronic module 100. This serves as a cause for a drop in the reliability of the electronic module 100 in the case where the electronic device 102 is susceptible to the negative effects of moisture.

It is an object of the present invention to solve the problems based on the stated conventional techniques by providing an electronic module capable of suppressing degradation in an internal electronic device and ensuring high reliability over the long term, even in the case where the electronic device is sensitive to moisture.

### SUMMARY OF THE INVENTION

In order to achieve the above object, the present invention provides an electronic module comprising: an electronic device in which an electronic element is provided on a flexible substrate that does not transmit water vapor; an edge sealant provided at a peripheral edge of the flexible substrate of the electronic device; and a water vapor barrier film provided so as to cover a region surrounded by the edge sealant; upon a square root of twice a diffusion coefficient of the edge sealant (guideline for the diffusion distance over a set amount of time) being K, K being not greater than 0.1 cm/√h; and the water vapor barrier film comprising a support member made of a transparent resin and at least one inorganic layer formed thereon, and the support member being disposed on a side on which the edge sealant is located.

The region surrounded by the edge sealant is preferably filled with a filling material.

In the water vapor barrier film, the support member is not greater than 250 μm thick, for example.

The edge sealant preferably has a water vapor transmission rate of not greater than 2.0 g/m²/day.

The edge sealant preferably contains polyisobutylene.

Preferably, the flexible substrate of the electronic device includes one or more metal layers and an insulating layer formed on the one or more metal layers, the electronic element including lower electrodes and a CIGS film layered together is formed on the insulating layer, and the edge sealant is provided so as to make contact with a top of the insulating layer or a top of each of the lower electrodes.

Preferably, a shock resistant/absorbing layer is provided on the water vapor barrier film, a pressure-resistant layer is provided on a bottom surface of the flexible substrate, and the shock resistant/absorbing layer and the pressure-resistant layer each comprise polycarbonate resin.

According to the present invention, the amount of moisture ingressing into an electronic module can be reduced, and degradation in an internal electronic device can be suppressed even in the case where the electronic device is sensitive to moisture, thus making it possible to prolong the lifespan of the module. As such, according to the present invention, a high reliability can be ensured for the electronic module over the long term.

### BRIEF DESCRIPTION OF THE DRAWINGS

FIG. 1A is a schematic cross-sectional view illustrating an electronic module according to an embodiment of the present invention, and FIG. 1B is a schematic plan view illustrating an electronic device in the electronic module illustrated in FIG. 1A.

FIG. 2 is a schematic cross-sectional view illustrating an example of a solar battery submodule shown as an electronic device in the electronic module according to an embodiment of the present invention.

FIG. 3 is a schematic cross-sectional view illustrating another example of an electronic module according to an embodiment of the present invention.

FIG. 4 is a graph showing a relationship between the thickness of a support member and the water vapor transmission rate.

FIG. 5A is a schematic plan view illustrating a glass plate used in a moisture ingress test, and FIG. 5B is a schematic cross-sectional view illustrating a test piece used in the moisture ingress test.

FIG. 6 is a schematic cross-sectional view illustrating a conventional electronic module.

### DETAILED DESCRIPTION OF THE INVENTION

Hereinafter, an electronic module according to the present invention will be described in detail based on a preferred embodiment illustrated in the appended drawings.

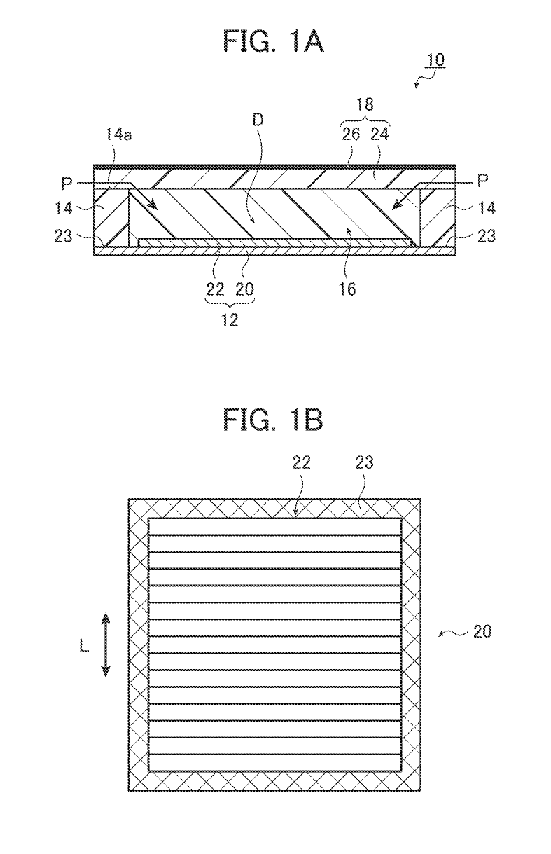

FIG. 1A is a schematic cross-sectional view illustrating the electronic module according to the embodiment of the present invention, and FIG. 1B is a schematic plan view illustrating an electronic device in the electronic module illustrated in FIG. 1A.

An electronic module 10 illustrated in FIG. 1A includes an electronic device 12, an edge sealant 14, a filling material 16, and a water vapor barrier film 18.

The electronic device 12 at least includes a flexible substrate 20 that does not allow water vapor to pass, and an electronic element 22 formed on the flexible substrate 20. Elements sensitive to moisture, such as a photoelectric conversion element including a photoelectric conversion layer such as a CIS film, a CIGS film, or the like, an organic EL element (OLED), an a-Si solar battery element and an organic thin-film solar battery element (OPV), and the like can be given as examples of the electronic element 22. The flexible substrate 20 and the electronic element 22 will be described in detail below.

As illustrated in FIG. 1B, the electronic element 22 is not formed at an edge portion 23 of the flexible substrate 20, and the edge sealant 14 (see FIG. 1A) is disposed at the edge portion 23 so as to surround the electronic element 22.

As illustrated in FIG. 1A, a region D surrounded by the edge sealant 14 is filled with the filling material 16, and the filling material 16 is provided so as to reach a top surface 14a of the edge sealant 14. The water vapor barrier film 18 is provided on the top surface 14a of the edge sealant 14 so as to cover the region D surrounded by the edge sealant 14 and filled with the filling material 16.

Although described in detail below, the water vapor barrier film 18 includes a support member 24 made of a transparent resin and a water vapor barrier layer 26 formed on the support member 24. The water vapor barrier film 18 is disposed with the support member 24 on the edge sealant 14 side, and light from the water vapor barrier film 18 side is incident on the electronic element 22 of the electronic device 12.

Rather than being provided with a backsheet, the electronic module 10 employs the flexible substrate 20 that does not allow water vapor to pass, and thus, as illustrated in FIG. 1A, has a structure in which a moisture ingress passage P is present only at the support member 24 of the water vapor barrier film 18. This makes it possible to cut the water vapor ingress cross-sectional area in half. Through this, the water vapor transmission rate can be reduced.

As opposed to this, in the conventional electronic module 100 illustrated in FIG. 6, a moisture ingress passage P is present at the support member 110a of the backsheet 110 in addition to the moisture ingress passage P present in the electronic module 10 according to the present embodiment. The electronic module 10 according to the present embodiment can reduce the amount of water vapor that ingresses by reducing the moisture ingress passage P beyond that in the conventional example. Through this, even in the case where the electronic element 22 of the electronic device 12 is sensitive to moisture, the degradation of the electronic element 22 of the electronic device 12 can be suppressed, which in turn makes it possible to prolong the lifespan of the electronic module 10. As such, according to the present invention, a high reliability can be ensured for the electronic module 10 over the long term.

The electronic module 10 can be manufactured as follows, for example.

First, the electronic device 12 is prepared. Next, the edge sealant 14 is disposed on lower electrodes of the electronic device 12 or the edge portion 23 exposed at the uppermost surface of the flexible substrate 20, and the filling material 16 in the form of a sheet having the same thickness as the edge sealant 14 is then disposed in the region D surrounded by the edge sealant 14. The water vapor barrier film 18 is then disposed with the support member 24 facing toward the edge sealant 14 side. In this layered state, a vacuum laminator having an elevating unit, an impingement baffle, and a heating unit, for example, is used to vacuum-laminate these elements under conditions of, for example, a temperature from 130 to 150° C. and vacuuming, pressing, and holding being carried out for from 15 to 30 minutes in total. Through this, the electronic module 10 illustrated in FIG. 1A can be manufactured.

Next, the respective configurations in the electronic module 10 will be described.

The edge sealant 14 prevents degradation in the performance of the electronic module 10 by suppressing moisture ingress at the edges of the electronic module 10 and suppressing moisture ingress into the electronic element 22, which is susceptible to a drop in performance due to moisture, from the exterior of the electronic module 10. The performance degradation can be suppressed particularly for the electronic element 22, which is susceptible to the effects of moisture.

As will be described below, with respect to the ingress of moisture, a diffusion coefficient indicating a diffusion distance per unit of time when transiting from a non-equilibrium state to an equilibrium state and a water vapor transmission rate indicating a moisture movement amount per unit of time in the equilibrium state (one being a wet atmosphere, the other being a dry atmosphere) are both defined for the edge sealant 14.

The diffusion coefficient indicates a distance over which moisture ingresses into the edge sealant 14 regardless of the amount of ambient moisture at the edge sealant 14, and indicates the degree of moisture ingress. On the other hand, the water vapor transmission rate indicates a moisture movement amount. In the edge sealant 14, by first defining the degree of moisture ingress (ingress distance) and then furthermore defining the amount of moisture ingress, the edge sealant 14 is prevented from acting as a moisture ingress passage, and degradation in the performance of the electronic element 22 is suppressed.

In the edge sealant 14, assuming that the square root of twice the diffusion coefficient is K, K=not greater than 0.1. K serves as a guideline for the diffusion distance over a set amount of time, and the unit of K is cm/√h (where √h is √hour). Note that when the diffusion coefficient is represented by d, K is represented as K=(2d)^{1/2}.

Here, the diffusion length of water moving within a matter is expressed as X=K×√t (Conference Paper NREL/CP-5200-47706, February 2011, Evaluation and Modeling of Edge-Seal Materials for Photovoltaic Applications).

By setting the stated K to not greater than 0.1 cm/√h, the moisture diffusion length can be shortened, and the ingress of moisture into the electronic module 10 from the edge sealant 14 can be suppressed.

The edge sealant 14 is formed using polyisobutylene (PIB), an ionomer, a thermoplastic elastomer (TPU), polyvinyl butyral (PVB), an olefin-based elastomer (TPO), and the like, for example. These primary materials may further include talc (hydrated magnesium silicate) or a hygroscopic material such as calcium oxide. Of these materials, polyisobutylene (PIB), ionomer, TPU, PVB, TPO to be used alone, or a mixture of polyisobutylene and talc or magnesium oxide is preferable.

Here, the support member 24 of the water vapor barrier film 18 is formed of a resin film such as PET or the like, as will be described below. PET, for example, has a water vapor transmission rate (WVTR) of 5 g/m²/day, and the edge sealant 14 will act as a moisture ingress passage if the water vapor transmission rate (WVTR) is not sufficiently lower than this. To prevent this, it is preferable for the edge sealant 14 to be made of any of the materials as described above, as long as the material has a water vapor transmission rate (WVTR) of not greater than 2.0 g/m²/day, which is not greater than half the water vapor transmission rate (WVTR) of the film made of resin such as PET that makes up the support member 24. As a result, the influence of moisture from the edge sealant 14 to the electronic element 22 of the electronic device 12 can be suppressed.

The filling material 16 seals the electronic element 22 of the electronic device 12. An ionomer resin, ethylene vinyl acetate (EVA), PVB, polyethylene (PE), an olefin-based adhesive, a polyurethane-based adhesive, or the like, for example, can be employed as the filling material 16. Aside from these, various types of materials typically employed as sealants in known solar battery modules can be used. Note that a thermoplastic olefin-based polymer resin and a thermoplastic polyurethane-based resin have superior adhesive properties and are thus preferable for use as the filling material 16.

Applying a primer to an adherend or carrying out corona treatment for improving the adhesive properties can serve to strengthen the adhesive properties with the filling material 16.

The water vapor barrier film 18 is for protecting the electronic device 12, and particularly the electronic element 22, from moisture.

In the water vapor barrier film 18, various types of resin films (plastic films) such as a PET film, a PEN film, and the like are employed for the support member 24 made of a transparent resin, for example.

As for the transmittance, the transparent resin preferably has a total light transmittance at wavelengths from 400 to 1,400 nm of 85% and more preferably not less than 90%.

The water vapor transmission rate can be reduced by setting the thickness of the support member 24 to not greater than 250 μm. Accordingly, it is preferable for the thickness of the support member 24 to be not greater than 250 μm.

The water vapor barrier layer 26 includes at least one layer of an inorganic compound (called an “inorganic layer” hereinafter), which provides water vapor barrier properties. Note that the inorganic layer may be oxidized near a border with the support member 24 or with an organic layer that will be described below.

The inorganic layer of the water vapor barrier layer 26 is made of an inorganic compound such as a diamond-like compound, a metal oxide, a metal nitride, a metal carbide, a metal oxynitride, a metal oxycarbide, or the like. Diamond-like carbon (DLC), a diamond-like carbon containing silicon, an oxide, nitride, carbide, oxynitride, or oxycarbide containing one or more types of metal selected from Si, Al, In, Sn, Zn, Ti, Cu, Ce, and Ta, and the like can be given as examples of the stated inorganic compound.

Of these, an oxide, nitride, or oxynitride of a metal selected from Si, Al, In, Sn, Zn, and Ti is preferable, and a metal oxide, nitride, or oxynitride of Si or Al is particularly preferable. These inorganic layers are formed through plasma CVD, sputtering, or the like, for example.

Meanwhile, the water vapor barrier film 18 may have a configuration in which, for example, an organic compound layer (also called an “organic layer” hereinafter) serving as a ground layer is formed on the support member 24 formed of any of various types of resin film such as PET film, PEN film, or the like, and the aforementioned inorganic layer is then formed on the organic layer. Configuring the water vapor barrier film 18 in this manner makes it possible to achieve higher water vapor barrier properties. Furthermore, the water vapor barrier film 18 may have a configuration in which an organic layer, an inorganic layer, and an organic layer serving as the water vapor barrier layer 26 are layered on the support member 24.

Acrylic resin, methacrylic resin, epoxy resin, polyester, a methacrylic acid-maleic acid copolymer, polystyrene, transparent fluorine resin, polyimide, fluorinated polyimide, polyamide, polyamide-imide, polyether imide, cellulose acylate, polyurethane, polyether ketone, polycarbonate, fluorene ring-modified polycarbonate, alicyclic-modified polycarbonate, fluorene ring-modified polyester, and the like can be given as examples of the organic compound serving as the ground layer. Of these, acrylic resin and methacrylic resin are particularly preferable.

This organic layer is formed through an application method using a known application unit, such as roll-coating or spray coating, or through flash vapor deposition, for example.

Meanwhile, in the water vapor barrier film 18, one or more layers that realize various types of functions such as an adhesion layer, a planarizing layer, an antireflection layer, or the like may be formed on at least one of the front surface and the back surface of the water vapor barrier film 18, as long as the required transparency can be ensured.

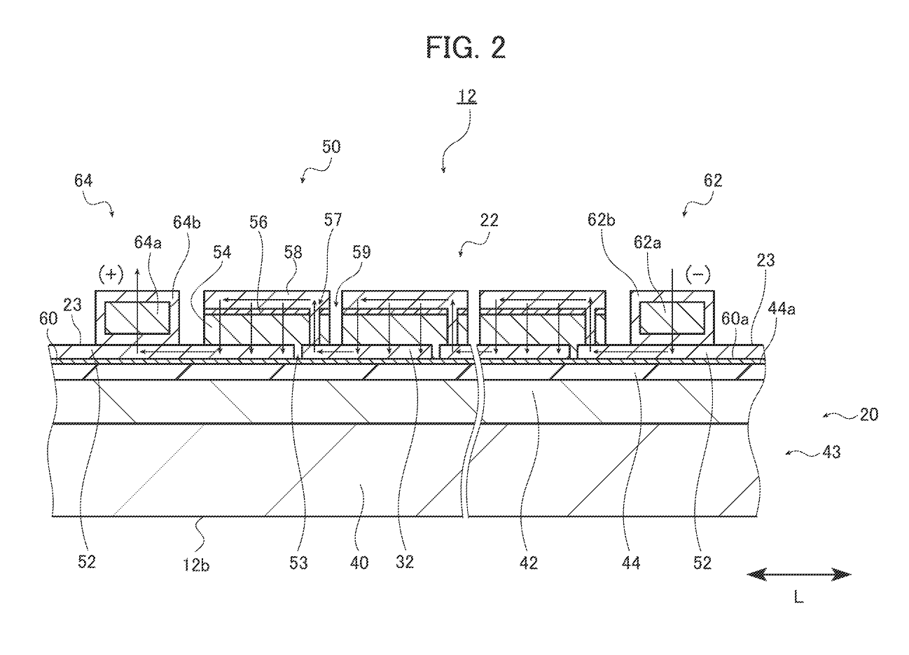

Next, the electronic device 12 will be described in detail with reference to FIG. 2.

A CIGS solar battery submodule will be described as an example of the electronic device 12.

In the electronic device 12 illustrated in FIG. 2, a plurality of solar battery cells (photoelectric conversion elements) 50 having layered structures are bonded in series on the flexible substrate 20 to form the electronic element 22. Each solar battery cell 50 is formed by layering a lower electrode 52, a photoelectric conversion layer 54 made of a CIGS semiconductor compound, a buffer layer 56, and an upper electrode 58. The solar battery submodule also includes a first conductive member 62 and a second conductive member 64. Note that the lower electrode 52 may also be called a “rear surface electrode”, and the upper electrode 58 may also be called a “transparent electrode.”

The flexible substrate 20 is, for example, a metal substrate including a base member 40, an Al (aluminum) base member 42, and an insulating layer 44.

The base member 40 and the Al base member 42 are formed integrally. Furthermore, the insulating layer 44 is an Al porous-structure anodic oxide film formed by anodizing the surface of the Al base member 42. Note that a clad base member formed by layering the base member 40 and the Al base member 42 integrally is called a metal base member 43.

The flexible substrate 20 has a flat plane shape, for example, and the specific shape and size thereof are determined as appropriate based on the size and the like of the solar battery submodule.

In the electronic device 12, carbon steel, heat-resistant steel, or stainless steel is employed for the (metal) base member 40 that makes up the flexible substrate 20.

Carbon steel for machine construction having a carbon content of not greater than 0.6 mass %, for example, is employed as the carbon steel. What is generally called S—C material, for example, is used for the carbon steel for machine construction.

Meanwhile, SUS 430, SUS 405, SUS 410, SUS 436, SUS 444, and the like can be used for the stainless steel. In addition to these, what is generally known as cold-rolled steel plate (SPCC) is employed as the base member 40. Furthermore, Kovar alloy (5 ppm/K), titanium, or a titanium alloy may be employed. Pure Ti (9.2 ppm/K) is used as the titanium, whereas a wrought alloy of Ti-6Al-4V or Ti-15V-3Cr-3Al-3Sn is used as the titanium alloy.

The thickness of the base member 40 affects the flexibility thereof, and thus it is preferable for the base member 40 to be thin within a range that does not result in an excessive lack of rigidity. Considering the balance between flexibility and strength (rigidity) as well as the ability to handle the material and the like, the thickness of the base member 40 is set to from 10 to 800 μm, for example, and is preferably set to from 30 to 300 μm, to ensure that the flexible substrate 20 is flexible. More preferably, the thickness is set to from 50 to 150 μm. Reducing the thickness of the base member 40 is desirable from the standpoint of raw material costs, and can also reduce the bending radius at which cracks are formed in the layers formed on the surface.

The Al base member 42 contains Al as its primary component; aluminum being the primary component refers to an aluminum content of not less than 90 mass %. Al, as well as various types of Al alloys, can be used for the Al base member 42.

Known raw materials described in the Aluminum Handbook, Fourth Edition (Japan Light Metals Association (1990)), for example, including 1000 series alloys such as JIS 1050, JIS 1100, and the like, 3000 series alloys such as JIS 3003, JIS 3004, JIS 3005, and the like, and 6000 series alloys such as JIS 6061, JIS 6063, JIS 6101, and the like, as well as internationally-registered alloys such as 3103A and the like, can be used for the Al base member 42.

Al having a purity of not less than 99 mass %, with few impurities is particularly preferable. 99.99 mass % Al, 99.96 mass % Al, 99.9 mass % Al, 99.85 mass % Al, 99.7 mass % Al, 99.5 mass % Al, or the like, is preferable in terms of the purity, for example.

Furthermore, industrial-use Al can also be used instead of high-purity Al. Using industrial-use Al is advantageous in terms of cost. However, from the standpoint of the insulative properties of the insulating layer 44, it is important that no Si be deposited within the Al.

The thickness of the Al base member 42 is not particularly limited and can be selected as desired, but the thickness is preferably not less than 0.1 μm but not greater than the thickness of the base member 40 in the completed electronic device 12. The thickness of the Al base member 42 drops due to pre-processing of the Al surface, the formation of the insulating layer 44 through anodization, the generation of an intermetallic compound at the face between the Al base member 42 and the base member 40 when forming the photoelectric conversion layer 54, and the like. In light of the drop in thickness caused by such factors, it is important for the thickness of the Al base member 42 during formation (described below) to be a thickness at which the Al base member 42 remains between the base member 40 and the insulating layer 44 in the completed electronic device 12. It is thus assumed that a thickness of from 10 to 50 μm is required in the Al base member 42 in order to form the insulating layer through anodization.

A surface roughness of a surface 44a of the insulating layer 44 is, for example, an arithmetic mean roughness Ra of not greater than 1 μm, and preferably not greater than 0.5 μm, and further preferably, not greater than 0.1 μm.

The insulating layer 44 is formed on the Al base member 42 (on the side opposite to the base member 40).

Here, the porous-structure anodic oxide film that makes up the insulating layer 44 is an aluminum oxide film having pores with a diameter of several tens of nm, and is resistant to bending and cracking caused by thermal expansion differences at high temperatures due to the film having a low Young's modulus.

The thickness of the insulating layer 44 is preferably not less than 2 μm, and is more preferably not less than 5 μm. The insulating layer 44 being excessively thick will result in a drop in flexibility as well as an increase in cost and time required to form the insulating layer 44, which is undesirable. Realistically, the thickness of the insulating layer 44 is not greater than a maximum of 50 μm, and preferably is not greater than 30 μm. Thus the preferred thickness of the insulating layer 44 is from 2 to 50 μm.

In the electronic device 12, for example, the flexible substrate 20 has a structure in which the insulating layer 44 (an insulative oxide film) that has a plurality of pores is formed through anodization on the metal base member 43 having the thickness from 50 to 200 μm, ensuring high insulative properties.

After the Al base member 42 has been anodized to form the insulating layer 44, the flexible substrate 20 may undergo special sealing treatment. This manufacturing process may include various types of steps in addition to the necessary steps. For example, it is preferable to obtain the flexible substrate 20 by performing a degreasing step for removing deposited rolling oil, a desmutting step for dissolving smut on the surface of the Al base member 42, a surface roughening step for roughening the surface of the Al base member 42, an anodizing step for forming the anodic oxide film on the surface of the Al base member 42, and a sealing step for sealing micropores in the anodic oxide film.

In the flexible substrate 20, each of the base member 40, the Al base member 42, and the insulating layer 44 have flexibility, in other words, are flexible, and thus the flexible substrate 20 as a whole is flexible. As a result, an alkali supply layer, lower electrodes, a phototransformation layer, upper electrodes, and the like which will be described below can be formed on the insulating layer 44 side of the flexible substrate 20 through the roll-to-roll method, for example.

For example, by adding a scribing step for separating and integrating elements between respective film-forming steps to manufacturing using the roll-to-roll method, the electronic element 22 with a plurality of solar battery cells 50 electrically connected in series can be manufactured.

The flexible substrate 20 is not limited to having the Al base member 42 and the insulating layer 44 formed on only one surface of the base member 40; a substrate in which the Al base member 42 is formed on both surfaces of the base member 40 and the insulating layer 44 is then formed on one Al base member 42, or a substrate in which the Al base member 42 and the insulating layer 44 are formed on both surfaces of the base member 40, may be used as the substrate. The flexible substrate 20 may be a single Al layer, in other words, a substrate in which an insulating layer formed of the aforementioned anodic oxide film is provided on an Al substrate. In addition, the metal base member 43 may have a single-layer structure aside from an Al substrate.

Note that a material in which a metal oxide film produced on the surface of the metal substrate through anodization serves as the insulative material can be used as the metal substrate. As such, zirconium (Zr), titanium (Ti), magnesium (Mg), copper (Cu), niobium (Nb), tantalum (Ta), and the like, as well as alloys thereof, can in particular be used in addition to aluminum (Al). However, aluminum is most preferable from the standpoint of cost and the properties required of the solar battery module.

Meanwhile, mild steel, or what is known as a clad member formed by rolling or hot-dipping the stated metal layers on a steel plate such as stainless steel plate, may be used for the substrate in order to improve thermal resistance.

In this manner, the flexible substrate 20 is composed of metals, alloys, oxides, and the like, and water vapor cannot penetrate due to the properties and film thicknesses thereof.

Here, an alkali supply layer 60, serving as a source for supplying an alkali metal to the photoelectric conversion layer 54, is formed between the insulating layer 44 (the flexible substrate 20) and the lower electrodes 52, in other words, on the surface 44a of the insulating layer 44. The alkali supply layer 60 is included in the electronic element 22.

Alkali metals, and Na in particular, are known for increasing photoelectric conversion efficiency when dispersed throughout the photoelectric conversion layer 54 made of CIGS.

The alkali supply layer 60 is a layer for supplying an alkali metal to the photoelectric conversion layer 54, and is a compound layer containing an alkali metal. By providing the alkali supply layer 60 between the insulating layer 44 and the lower electrodes 52, the alkali metal disperses throughout the photoelectric conversion layer 54 through the lower electrodes 52 when the photoelectric conversion layer 54 is formed, which makes it possible to improve the conversion efficiency of the photoelectric conversion layer 54.

Although not particularly limited, it is most preferable for the alkali supply layer 60 to be formed through the liquid-phase method. The alkali supply layer 60 formed through the liquid-phase method will be described in detail hereinafter. The alkali supply layer 60 is, for example, an alkali metal silicate layer.

An alkali metal in the alkali metal silicate layer is preferably sodium, and the alkali metal silicate layer more preferably contains two metals, one being sodium, the other being lithium or potassium, as exemplified by lithium and sodium or potassium and sodium. The insulative properties can be enhanced by employing lithium or potassium in combination with sodium, which makes it possible to improve the power generation efficiency.

Sodium silicate, lithium silicate, and potassium silicate can be given as preferred examples of the silicon source and alkali metal source for the alkali metal silicate layer formed through the liquid-phase method. A wet method, a dry method, and the like are known as methods for manufacturing sodium silicate, lithium silicate, and potassium silicate, and these can be manufactured by dissolving silicon oxide with sodium hydroxide, lithium hydroxide, and potassium hydroxide, respectively. Alkali metal silicates having various molar ratios are commercially available, and these can be used as well.

Sodium silicates, lithium silicates, and potassium silicates having various molar ratios are commercially available as the sodium silicate, the lithium silicate, and the potassium silicate. The SiO₂/A₂O (A:alkali metal) molar ratio is often used as an index expressing a ratio between silicon and an alkali metal. For example, lithium silicate 35, lithium silicate 45, lithium silicate 75, and the like, produced by Nissan Chemical Industries, Ltd., are available as lithium silicates. No. 1 potassium silicate, No. 2 potassium silicate, and the like are commercially available as potassium silicates.

Sodium orthosilicate, sodium metasilicate, No. 1 sodium silicate, No. 2 sodium silicate, No. 3 sodium silicate, No. 4 sodium silicate, and the like are known as sodium silicates, and high-molar sodium silicates in which the molar ratio of silicon has been increased to several tens are also commercially available.

In the case where sodium and lithium or potassium are contained as two alkali metals, two types of supply sources, such as sodium silicate and lithium silicate or sodium silicate and potassium silicate, may be used. For example, an alkali metal silicate layer containing lithium silicate and sodium silicate or potassium silicate and sodium silicate can also be manufactured by mixing, with water at a desired ratio, lithium silicate and sodium hydroxide or lithium hydroxide and sodium silicate in the case where the alkali metal silicate layer contains lithium silicate and sodium silicate, and potassium hydroxide and sodium silicate or potassium silicate and sodium hydroxide in the case where the alkali metal silicate layer contains potassium silicate and sodium silicate. Furthermore, a lithium salt, a potassium salt, or a sodium salt may be respectively added as the supply source. A nitrate, a sulphate, an acetate, a phosphate, a chloride, a bromide, an iodide, or the like is used, for example.

An application liquid for the alkali metal silicate layer according to the present invention can be obtained by mixing the aforementioned silicon source and alkali metal source with water at a desired ratio. The viscosity of the application liquid can be adjusted by varying the amount of water added, and suitable application conditions can therefore be set. The method for applying the application liquid on the substrate is not particularly limited, and a method such as a doctor blade method, a wire bar method, a gravure method, a spray method, a dip coat method, a spin coat method, a capillary coat method, or the like can be used, for example.

The alkali metal silicate layer can be manufactured through heating treatment after the application liquid is applied on the substrate, and at this time, the heating treatment is carried out in an atmosphere having a lower pressure than atmospheric pressure, preferably a total pressure of not greater than 1×10⁴ Pa, more preferably a total pressure of not greater than 1×10² Pa, even more preferably not greater than 1 Pa, and particularly preferably not greater than 1×10⁻² Pa.

The thickness of the alkali metal silicate layer after the heating treatment is from 0.01 to 2 μm, and preferably from 0.05 to 1.5 μm, and more preferably from 0.1 to 1 μm. When the alkali metal silicate layer is thicker than 2 μm, the alkali metal silicate contracts by a greater amount during the heating treatment, making it easier for cracks to form, which is undesirable.

Note that the alkali metal silicate layer may contain boron, and boron forms uniform glass when incorporated into a glass network composed of silicon and oxygen. This changes the structure of the glass at the micro level, improving the stability of the alkali metal ions within the glass. This in turn suppresses the release of alkali metal ions, which is presumed to ensure that segregation of alkali metal ions to the surface does not occur. Accordingly, the alkali metal silicate layer is formed as a single layer of boron, silicon, and an alkali metal, and does not include, for example, a boron-containing layer formed on the surface of the alkali metal silicate layer.

Boric acid, a borate such as sodium tetraborate, and the like can be given as examples of boron sources.

As described thus far, it is most preferable to form an Na-containing glass layer (liquid-phase glass layer) for the alkali supply layer 60 by firing sodium silicate (Na₂O.nSiO₂.xH₂O n=3 to 3.3), lithium silicate, and boric acid (H₃BO₃).

In addition to formation through the liquid-phase method, sputtering may be employed to form a soda lime glass sputter layer as the alkali supply layer 60.

There are no particular limitations on the alkali supply layer 60, and various types of layers that includes a compound containing an alkali metal (a composition containing an alkali metal compound) as its primary component, such as NaO₂, Na₂S, Na₂Se, NaCl, NaF, sodium molybdate, or the like, can be used as well. A compound primarily composed of SiO₂ (silicon oxide) and containing NaO₂ (sodium oxide) is particularly preferable.

A compound of SiO₂ and NaO₂ has poor moisture resistance properties and an Na component is more likely to be separated to form a carbonate and hence an oxide containing three components of Si, Na and Ca as the metal components containing Ca added thereto is more preferable.

Note that the source for supplying the alkali metal to the photoelectric conversion layer 54 is not limited only to the alkali supply layer 60 in the present invention.

For example, in the case where the insulating layer 44 is a porous anodic oxide film as described earlier, a compound containing an alkali metal can also be introduced into the pores of the insulating layer 44 in addition to the alkali supply layer 60, and the insulating layer 44 may then serve as a source for supplying the alkali metal to the photoelectric conversion layer 54. Alternatively, the alkali supply layer 60 in particular may be omitted, and a compound containing an alkali metal may be introduced into the pores of the insulating layer 44 only, which may then serve as a source for supplying the alkali metal to the photoelectric conversion layer 54.

As one example, in the case where sputtering is used to form the alkali supply layer 60, only the alkali supply layer 60 can be formed alone, without a compound containing an alkali metal being present in the insulating layer 44. On the other hand, in the case where the insulating layer 44 is a porous anodic oxide film and the alkali supply layer 60 is formed through a sol-gel reaction or by dehydration drying of a sodium silicate aqueous solution, a compound containing an alkali metal can be introduced into the porous layer of the insulating layer 44 in addition to the alkali supply layer 60, and thus both the insulating layer 44 and the alkali supply layer 60 can serve as sources for supplying the alkali metal to the photoelectric conversion layer 54.

In the electronic device 12, the lower electrodes 52 are formed on the alkali supply layer 60 so as to be disposed with predetermined gaps (P1) 53 therebetween. The photoelectric conversion layer 54 is formed on the lower electrodes 52 so as to fill the gaps 53 between the respective lower electrodes 52. The buffer layer 56 is formed on the surface of the photoelectric conversion layer 54.

The photoelectric conversion layer 54 and the buffer layer 56 are disposed on the lower electrodes 52 with predetermined gaps (P2) 57 provided therein. Note that the gaps 53 between the lower electrodes 52 and the gaps 57 in the photoelectric conversion layer 54 (the buffer layer 56) are formed at different locations in the direction in which the solar battery cells 50 are arranged.

Furthermore, the upper electrodes 58 are formed on the surface of the buffer layer 56 so as to fill the gaps 57 in the photoelectric conversion layer 54 (the buffer layer 56).

The upper electrodes 58, the buffer layer 56, and the photoelectric conversion layer 54 are disposed with predetermined gaps (P3) 59 provided therein. The gaps 59 are provided at different locations from the gaps between the adjacent lower electrodes 52 and the gaps in the photoelectric conversion layer 54 (the buffer layer 56).

In the electronic device 12, the respective solar battery cells 50 are electrically connected in series in a longer direction (a direction of an arrow L) of the flexible substrate 20 by the lower electrodes 52 and the upper electrodes 58.

The lower electrodes 52 are formed of an Mo film, for example. The photoelectric conversion layer 54 is formed of a semiconductor compound having a photoelectric conversion function, for example, a CIS film or a CIGS film. Furthermore, the buffer layer 56 is formed of CdS, for example, and the upper electrodes 58 are formed of ZnO, for example.

Note that the solar battery cells 50 are formed so as to extend longer in a width direction orthogonal to the longer direction L of the flexible substrate 20. As such, the lower electrodes 52 and the like also extend longer in the width direction of the flexible substrate 20.

As illustrated in FIG. 2, the first conductive member 62 is connected on the rightmost lower electrode 52. The first conductive member 62 is for bringing an output from a negative electrode (described below) to the exterior.

The first conductive member 62 is, for example, a long, thin, band-shaped member, extending in a substantially straight line in the width direction of the flexible substrate 20, and connected to the rightmost lower electrode 52. Meanwhile, as illustrated in FIG. 2, the first conductive member 62 is configured by, for example, covering a copper ribbon 62a with a cover material 62b made of an indium-copper alloy. The first conductive member 62 is connected to the lower electrode 52 through ultrasonic soldering, for example. Alternatively, the first conductive member 62 may be a conductive tape in which a copper foil is hot-dipped in In—Sn and provided with an embossed structure, and the conductive tape is connected by being laminated to the lower electrode 52 through pressure-bonding using a roller.

On the other hand, the second conductive member 64 is formed on the leftmost lower electrode 52.

The second conductive member 64 is for bringing an output from a positive electrode (described below) to the exterior, and like the first conductive member 62, is a long, thin, band-shaped member that extends in a substantially straight line in the width direction of the flexible substrate 20 and is connected to the leftmost lower electrode 52.

The second conductive member 64 has a similar configuration as the first conductive member 62, for example, a configuration in which a copper ribbon 64a is covered with a covering material 64b made of an indium-copper alloy, but like the first conductive member 62, may be connected using a conductive tape.

Note that the first conductive member 62 and the second conductive member 64 are extended to the exterior and are connected to terminals or the like when configured as a module.

In the electronic device 12 illustrated in FIG. 2, the lower electrodes 52 exposed at end portions in the longer direction L correspond to the edge portion 23 illustrated in FIG. 1B, and the edge sealant 14 is provided at that location. Note that the edge sealant 14 may be provided on a surface 60a of the alkali supply layer 60 by removing the lower electrodes 52 through scribing or the like, rather than on the lower electrodes 52. Furthermore, the lower electrodes 52 and the alkali supply layer 60 may be removed through scribing or the like, and the edge sealant 14 may be provided on the surface 44a of the insulating layer 44. In either case, a favorable seal with the edge sealant 14 can be achieved, which makes it possible to suppress the ingress of moisture into the electronic module 10.

In the electronic device 12, when light from the upper electrode 58 side is incident on the solar battery cells 50, the light traverses the upper electrodes 58 and the buffer layer 56, producing electromotive force at the photoelectric conversion layer 54, and a current moving from the upper electrodes 58 toward the lower electrodes 52 is produced, for example. Note that the arrows in FIG. 2 indicate the direction of the current, and the direction in which electrons move is opposite from the direction of the current. As such, in the electronic element 22, the leftmost lower electrode 52 in FIG. 2 serves as the positive electrode (a plus electrode) and the rightmost lower electrode 52 in FIG. 2 serves as the negative electrode (a minus electrode).

The power produced by the electronic device 12 can be extracted to the exterior of the electronic device 12 from the first conductive member 62 and the second conductive member 64.

Here, the first conductive member 62 serves as the negative electrode and the second conductive member 64 serves as the positive electrode. However, the polarities of the first conductive member 62 and the second conductive member 64 may be reversed, and may be altered as appropriate in accordance with the configuration of the solar battery cell 50, the configuration of the electronic device 12, and the like.

Meanwhile, although the solar battery cells 50 are formed so as to be connected in series in the longer direction L of the flexible substrate 20 by the lower electrodes 52 and the upper electrodes 58, the invention is not limited thereto. For example, the solar battery cells 50 may be formed so that the solar battery cells 50 are connected in series in the width direction by the lower electrodes 52 and the upper electrodes 58.

The lower electrodes 52 and the upper electrodes 58 are both elements for extracting a current produced at the photoelectric conversion layer 54. The lower electrodes 52 and the upper electrodes 58 are both made of conductive materials. It is necessary for the upper electrodes 58, which are on a light-incident side, to be translucent.

The lower electrodes 52 are made of, for example, Mo, Cr, or W, or a combination thereof. The lower electrodes 52 may have a single-layer structure, or may have a layered structure including two layers or the like. It is preferable for the lower electrodes 52 to be made of Mo.

The lower electrodes 52 are preferably not less than 100 nm thick, and more preferably from 0.45 to 1.0 μm thick.

The method for forming the lower electrodes 52 is not particularly limited, and the lower electrodes 52 can be formed through a gas-phase deposition technique such as electron beam deposition, sputtering, or the like.

The upper electrodes 58 are made of, for example, ZnO, ITO (indium tin oxide), or SnO₂ to which Al, B, Ga, In, Sb, or the like has been added, or a combination thereof. The upper electrodes 58 may have a single-layer structure, or may have a layered structure including two layers or the like. The thickness of the upper electrodes 58 is not particularly limited, but from 0.3 to 1 μm is preferable.

Furthermore, the method for forming the upper electrodes 58 is not particularly limited, and a gas-phase deposition technique such as electron beam deposition, sputtering, CVD, or the like, or a liquid application method can be used.

The buffer layer 56 is formed to protect the photoelectric conversion layer 54 when the upper electrodes 58 are being formed and to allow light incident on the upper electrodes 58 to penetrate to the photoelectric conversion layer 54.

The buffer layer 56 is made of, for example, CdS, ZnS, ZnO, ZnMgO, or ZnS(O, OH), or a combination thereof.

Preferably, the buffer layer 56 is from 0.03 to 0.1 μm thick. The buffer layer 56 is formed through CBD (chemical bath deposition), for example.

The photoelectric conversion layer 54 is a layer that produces a current by absorbing light that has traversed the upper electrodes 58 and the buffer layer 56 and reached the photoelectric conversion layer 54, and has a photoelectric conversion function. The photoelectric conversion layer 54 is formed of a GIGS film, and the GIGS film is made of a semiconductor having a chalcopyrite crystal structure. The composition of the GIGS film is, for example, Cu(In₁₋ₓGaₓ)Se₂(CIGS).

1) Multisource deposition, 2) selenization, 3) sputtering, 4) hybrid sputtering, 5) mechanochemical processing, and the like are known as methods for forming the GIGS film.

Screen printing, a close space sublimation method, MOCVD, and a spray method (a wet deposition technique) can be given as other methods for forming the CIGS film. For example, crystals having a desired composition can be obtained through screen printing (a wet deposition technique), spraying (a wet deposition technique), or the like, by forming a particulate film containing a group Ib element, a group IIIb element, and a group VIb element on a substrate and subjecting the resultant to pyrolysis treatment or the like (this may be pyrolysis treatment in a group VIb element atmosphere) (JP 9-74065 A, JP 9-74213 A, and the like).

Such formation methods all exhibit a favorable photoelectric conversion efficiency at not less than 500° C. when the CIGS is formed on the substrate, but multisource deposition, which features a short processing time, is preferable when considering manufacture using the roll-to-roll method. Specifically, a bilayer method is preferable.

As described above, the electronic device 12 according the present invention is manufactured by bonding the solar battery cells 50 on the flexible substrate 20 in series, and this manufacturing method may be carried out in the same manner as for various types of known solar batteries.

An example of a method for manufacturing the electronic device 12 illustrated in FIG. 2 will be described hereinafter.

First, the flexible substrate 20 formed as described above is prepared. Next, a liquid mixture of Na₄SiO₄, Li₄SiO₄, and H₃BO₃, for example, is fired on the surface 44a of the insulating layer 44 of the flexible substrate 20 to form an Na-containing glass layer as the alkali supply layer 60. Note that a soda lime glass sputter layer may be formed as the alkali supply layer 60 through sputtering.

Next, an Mo film to serve as the lower electrodes 52 is formed on the surface of the alkali supply layer 60 through sputtering, for example, using a deposition device.

Next, the Mo film is scribed at predetermined positions using laser scribing, for example, to form the gaps 53 extending in the width direction of the flexible substrate 20. Through this, the lower electrodes 52 are formed in a state in which they are separated from each other by the gaps 53.

Next, a CIGS film is formed as the photoelectric conversion layer 54 (a p-type semiconductor layer) so as to cover the lower electrodes 52 and fill the gaps 53. This CIGS film is formed through any of the aforementioned deposition methods.

Next, a CdS layer (n-type semiconductor layer) to serve as the buffer layer 56 is formed on the photoelectric conversion layer 54 (CIGS film) through CBD (chemical bath deposition), for example. A p-n junction semiconductor layer is formed as a result.

Next, the gaps 57 that extend in the width direction of the flexible substrate 20 and reach the lower electrodes 52 are formed at predetermined positions in the arrangement direction of the solar battery cells 50 which are different from those of the gaps 53, through scribing such as laser scribing, for example.

Next, for example, an ITO layer or a ZnO layer to which Al, B, Ga, Sb, or the like has been added, which serves as the upper electrodes 58 is formed on the buffer layer 56 through sputtering or liquid application so as to fill the gaps 57.

Next, the gaps 59 that extend in the width direction of the flexible substrate 20 and reach the lower electrodes 52 are formed at predetermined positions in the arrangement direction of the solar battery cells 50 which are different from those of the gaps 53 and the gaps 57, through scribing such as laser scribing, for example. The solar battery cells 50 are formed as a result.

Next, the solar battery cells 50 formed on the lower electrodes 52 at the left and right ends in the longer direction L of the flexible substrate 20 are removed through laser scribing or mechanical scribing, for example, revealing the lower electrodes 52. Next, the first conductive member 62 is connected on the rightmost lower electrode 52 and the second conductive member 64 is connected on the leftmost lower electrode 52 using ultrasonic soldering, for example. As a result, the electronic element 22 in which the plurality of solar battery cells 50 are electrically connected in series can be formed on the flexible substrate 20, as illustrated in FIG. 2.

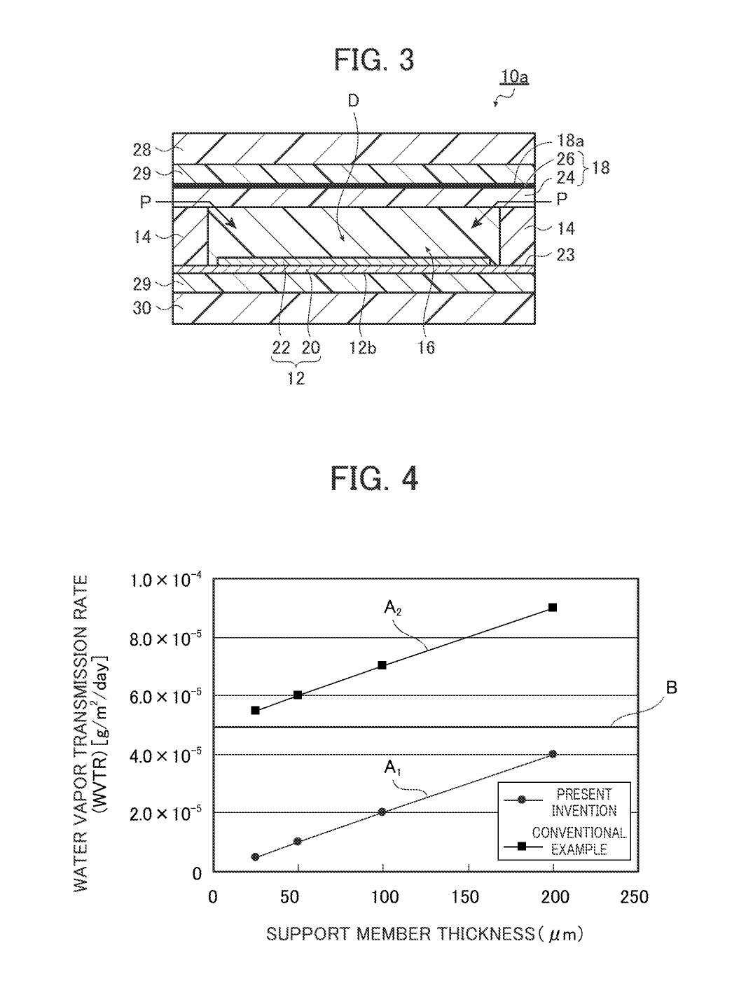

In the present embodiment, a shock resistant/absorbing layer 28 may be provided on a surface 18a of the water vapor barrier film 18 (the surface of the water vapor barrier layer 26) via a resin layer 29 and a pressure-resistant layer 30 may be provided on a bottom surface 12b of the electronic device 12 (a bottom surface of the flexible substrate 20) via the resin layer 29, as in an electronic module 10a illustrated in FIG. 3, for example. The shock resistant/absorbing layer 28 and the pressure-resistant layer 30 are made of polycarbonate resin, for example.

The resin layer 29 used for the shock resistant/absorbing layer 28 and the pressure-resistant layer 30 can use the same material as the filling material 16, and thus detailed descriptions thereof will be omitted here.

In the case where the electronic module 10 is installed outside, rain, hail, sleet, snow, rocks, and the like may collide therewith, but the shock resistant/absorbing layer 28 protects the electronic device 12 from such external forces, impact, and the like from the exterior. The shock resistant/absorbing layer 28 also protects the electronic module 10 from dirt and the like, and also suppresses a drop in the amount of light incident on the electronic device 12 caused by such dirt.

The pressure-resistant layer 30 protects the underside of the electronic module 10.

Note that the shock resistant/absorbing layer 28 and the pressure-resistant layer 30 are from 0.2 to 3 mm thick, for example, and preferably are from 1.0 to 2.0 mm thick.

If the shock resistant/absorbing layer 28 and the pressure-resistant layer 30 are less than 0.2 mm thick, those layers cannot sufficiently protect the electronic device 12 from external forces, impact, and the like from the exterior. On the other hand, if the shock resistant/absorbing layer 28 and the pressure-resistant layer 30 are greater than 3 mm thick, there is a greater temperature distribution in the vertical direction during vacuum lamination, which may result in the electronic module 10 warpage. A thinner configuration is desirable also from the standpoint of material costs.

The polycarbonate resin that makes up the shock resistant/absorbing layer 28 and the pressure-resistant layer 30 has a linear expansion coefficient of 60 ppm/K, which is six times the 10 ppm/K of the flexible substrate 20. As such, a great interior distortion acts on the electronic module 10a. However, according to the electronic module 10a, there is a favorable seal between the edge sealant 14 and the electronic device 12 and between the edge sealant 14 and the water vapor barrier film 18, and thus the same effects as those of the electronic module 10 can be achieved. Moreover, the electronic module 10a has a structure wherein the shock resistant/absorbing layer 28 and the pressure-resistant layer 30 are disposed on respective ends, and thus has superior anti-shock properties.

The electronic module 10a can also be manufactured by disposing the edge sealant 14 at the edge portion 23 of the flexible substrate 20 of the electronic device 12, filling with the filling material 16, disposing the water vapor barrier film 18, furthermore disposing the shock resistant/absorbing layer 28 and the pressure-resistant layer 30 via the resin layer 29, and then carrying out vacuum lamination on that layered structure using a vacuum laminator, in the same manner as with the electronic module 10.

The present invention is basically configured as described thus far. Although an electronic module according to the present invention has been described in detail thus far, the present invention is not limited to the aforementioned embodiment, and it goes without saying that various improvements or modifications may be made without departing from the essential spirit of the present invention.

### EXAMPLES

The electronic module according to the present invention will be described in further detail hereinafter.

In EXAMPLES, an electronic module according to Example 1 described below and a conventional electronic module according to Comparative Example 1 were manufactured, the water vapor transmission rates thereof were measured, and the moisture transmission rates were evaluated. The results are illustrated in FIG. 4.

### Example 1

In Example 1, the electronic module 10 configured as illustrated in FIGS. 1A and 1B, having the CIGS solar battery submodule illustrated in FIG. 2, serves as the electronic device.

In Example 1, a substrate configured by forming a 10 μm-thick anodic oxide film as the insulating layer 44 on the surface of a clad member of Al (40 μm thick)/SUS (70 μm thick)/Al (40 μm thick) was used as the flexible substrate 20. The size of the flexible substrate was 30 cm×30 cm.

A liquid mixture of sodium silicate (Na₂O.nSiO₂.xH₂O n=3 to 3.3), lithium silicate, and boric acid (H₃BO₃) was fired to form a 200 nm-thick, Na-containing glass layer as the alkali supply layer 60 on the surface of the anodic oxide film.

A 200 nm-thick Mo film was formed as the lower electrodes 52 through sputtering. Then, the solar battery cells 50 were manufactured by layering the photoelectric conversion layer 54 made of a CIGS semiconductor compound, the buffer layer 56, and the upper electrodes 58 on the lower electrodes 52 (Mo film), as with the solar battery cells 50 illustrated in FIG. 2.

The edge portion 23 of the flexible substrate 20 illustrated in FIG. 1B, in other words, a range of 10 to 20 mm from the outer edges of the substrate, is removed to the photoelectric conversion layer 54 through scribing, thus exposing the Mo film (the lower electrodes 52).

The edge sealant 14, which is primarily composed of polyisobutylene, was disposed at the edge portion 23 with a width of not less than 1 cm, and an EVA resin serving as the filling material 16 was disposed in portions on the inner side of the edge sealant 14 where the photoelectric conversion layer is present. The water vapor barrier film 18 was then disposed thereon with the water vapor barrier layer 26 on the light-incidence surface side. The water vapor barrier film 18 includes a 100 μm-thick PET support member 24, an organic layer, and an SiN inorganic layer (the water vapor barrier layer 26), in that order from the side on which the electronic device 12 is located. Note that the SiN inorganic layer may be oxidized near the border.

With the respective members layered in this manner, the members were laminated and sealed through a vacuum lamination process using a vacuum laminator for 20 minutes at a temperature of 140° C., thus creating a vapor-sealed structure, and obtaining the electronic module 10.

### Comparative Example 1

In Comparative Example 1, the electronic module 100 configured as illustrated in FIG. 6, having the CIGS solar battery submodule illustrated in FIG. 2, serves as the electronic device.

Comparative Example 1 differs from Example 1 in that the backsheet 110 is provided, and the electronic device 102 is located entirely within the filling material 16; other configurations are the same as those in Example 1, and thus detailed descriptions thereof will be omitted.

In Comparative Example 1, the water vapor barrier film 108 was disposed on the front surface side of the electronic device 102, and the backsheet 110 was disposed on the rear surface side.

In the backsheet 110, a 250 μm-thick PET film, a 50 μm-thick stainless steel plate (SUS plate), and a white coating layer were layered in that order from the side on which the electronic device 102 was located.

The water vapor barrier film has the same configuration as in Example 1. As such, detailed descriptions thereof will be omitted.

In Comparative Example 1, the edge sealant 106 that is primarily composed of polyisobutylene is disposed in an edge portion of the backsheet 110, an EVA resin serving as the filling material 104 is then disposed on the backsheet 110 surrounded by the edge sealant 106, the electronic device 102 is disposed thereon, and then the EVA resin is furthermore disposed on the electronic device 102. The water vapor barrier film 108 is then disposed, with the support member 108a facing the edge sealant 106, so as to cover the EVA resin.

With the respective members layered in this manner, the members were laminated and sealed through a vacuum lamination process using a vacuum laminator for 20 minutes at a temperature of 140° C., thus obtaining the electronic module 100.

Note that the edge sealant 106 is adjacent to the support member 108a of the water vapor barrier film 108 and the backsheet 110, and does not make contact with the electronic device 102.

In Example 1 and Comparative Example 1, the thickness of the support members in the water vapor barrier films were varied between 200 μm, 100 μm, 50 μm, and 30 μm, and the water vapor transmission rate was measured at each thickness.

The water vapor transmission rate was measured as follows. First, a substrate deposited with Ca was disposed on the CIGS solar battery submodule prior to the sealing process, and then the sealing was carried out. The water vapor transmission rate was then measured in an atmosphere having a temperature of 40° C. and a relative humidity of 90%, using the method disclosed in G. Nisato, P. C. P. Bouten, P. J. Slikkerveer et al, SID Conference Record of the International Display Research Conference, pp. 1435 to 1438 (called “Document A” hereinafter).

A₁ in FIG. 4 indicates changes in the water vapor transmission rate (WVTR) upon varying the thickness of the support member in the water vapor barrier film, with the electronic module configuration according to the present invention. A₂, meanwhile, indicates changes in the water vapor transmission rate (WVTR) upon varying the thickness of the support member in the water vapor barrier film, with the conventional module configuration. Note that a straight line B indicates the water vapor transmission rate (WVTR) performance required for electronic modules.

As shown in FIG. 4, according to the conventional electronic module 100, the water vapor barrier film does not meet the required performance even when the thickness of the support member is varied. As opposed to this, the configuration according to the present invention provides a water vapor ingress suppression performance that cannot be achieved by the conventional electronic module 100 that uses a backsheet. Note that with the electronic module according to Example 1 (the module according to the present invention), a thinner support member results in an improved water vapor transmission rate when the thickness is not greater than 250 μm.

### Example 2

In this example, the effects of the diffusion coefficient of the edge sealant was confirmed.

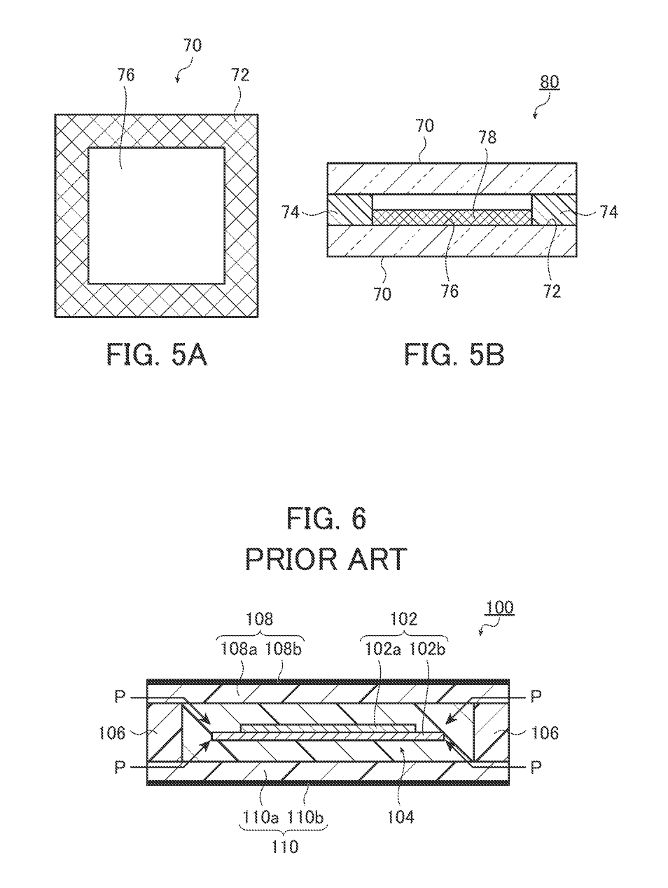

In this example, a 5 cm×5 cm glass plate 70, illustrated in FIG. 5A, is used. As illustrated in FIG. 5B, a 1 cm-wide edge sealant 74 is disposed on an edge portion 72 of the glass plate 70, and a Ca deposition plate 78 is disposed on a surface 76 of the glass plate 70 surrounded by the edge sealant 74. The glass plate 70 illustrated in FIG. 5A is then laminated so as to cover the Ca deposition plate 78, and a test piece 80 is prepared as a result.

The test piece 80 was moved to an atmosphere having a temperature of 85° C. and a relative humidity of 85% and left for 1,000 h; a suppressive effect was determined to be present in the case where the Ca in the Ca deposition plate 78 did not fade, whereas a suppressive effect was determined to be insufficient in the case where the Ca showed fading. In Table 1, a suppressive effect being present is indicated as “good”, whereas a suppressive effect being absent is indicated as “NG.”

The diffusion coefficient effects were confirmed for polyisobutylene (PIB), ionomer, thermoplastic elastomer (TPU), polyvinyl butyral (PVB), and ethylene vinyl acetate (EVA) as the materials of the edge sealant 74, as shown in Table 1. The results are shown in Table 1.

TABLE 1

| | Square Root of | |
|---|---|---|
| | Twice the | |
| | Diffusion | Moisture |
| | Coefficient: | Suppression |
| Edge Sealant | K(cm/√h) | Effect |
| PIB | 0.018 | Good |
| Ionomer | 0.067 | Good |
| TPU | 0.23 | NG |
| PVB | 0.25 | NG |
| EVA | 0.38 | NG |

As shown in Table 1, when the value of K (the square root of twice the diffusion coefficient) is not greater than 0.1, favorable results were obtained as the edge sealant.

### Example 3

In this example, electronic modules according to Experimental Examples 1 to 4 indicated below were manufactured and the moisture transmission rate was evaluated 10 times; the moisture ingress suppression was evaluated by confirming how many times a moisture suppression effect was achieved. The results are shown in Table 2.

As in Example 1, a substrate on which Ca was deposited before sealing was disposed on the solar battery submodule and the water vapor transmission rate was measured in an atmosphere having a temperature of 40° C. and a relative humidity of 90%, using the method disclosed in the aforementioned Document A. As such, detailed descriptions thereof will be omitted.

### Experimental Example 1

Experimental Example 1 used the electronic module according to Example 1. As such, detailed descriptions thereof will be omitted.

### Experimental Example 2

Experimental Example 2 has the same configuration as the electronic module 10a illustrated in FIG. 3; compared to Experimental Example 1, the polycarbonate resin shock resistant/absorbing layer 28 is provided on the surface 18a of the water vapor barrier film 18 (the surface of the water vapor barrier layer 26) via the resin layer 29, and the polycarbonate resin pressure-resistant layer 30 is provided on the bottom surface 12b of the electronic device 12 (the bottom surface of the flexible substrate 20) via the resin layer 29. Other configurations are the same as those in Experimental Example 1, and thus detailed descriptions thereof will be omitted.

### Experimental Example 3

Experimental Example 3 differs from Example 1 in that rather than being on the lower electrodes (Mo film), the edge sealant is on the photoelectric conversion layer (the CIGS layer) thereabove; other configurations are the same as in Example 1. As such, detailed descriptions thereof will be omitted.

### Experimental Example 4

Experimental Example 4 differs from Experimental Example 2 in that rather than being on the lower electrodes (Mo film), the edge sealant is on the photoelectric conversion layer (the CIGS layer) thereabove; other configurations are the same as in Experimental Example 2. As such, detailed descriptions thereof will be omitted.

TABLE 2

| | | | Times |
|---|---|---|---|
| | | | Moisture |
| | | | Suppression |
| | | | Effect |
| | | Number of | Achieved |
| | Structure | Tests (No.) | (No.) |
| EXPERIMENTAL | Electronic Module | 10 | 10 |
| EXAMPLE 1 | According to | | |
| | Example 1 | | |
| EXPERIMENTAL | Example 1 + | 10 | 10 |
| EXAMPLE 2 | Polycarbonate | | |
| | Layer | | |
| EXPERIMENTAL | Edge Sealant at | 10 | 7 |
| EXAMPLE 3 | CIGS Layer | | |
| EXPERIMENTAL | Edge Sealant at | 10 | 2 |
| EXAMPLE 4 | CIGS Layer + | | |
| | Polycarbonate | | |
| | Layer | | |

As shown in Table 2, in Experimental Example 1 and Experimental Example 2, the edge sealant is provided on the lower electrodes (Mo film), and the moisture suppression effect was achieved in all tests.

In Experimental Example 2, the polycarbonate resin shock resistant/absorbing layer 28 and the polycarbonate pressure-resistant layer 30 are provided. This polycarbonate resin has a linear expansion coefficient of 60 ppm/K, which is six times the 10 ppm/K of the base member, and thus a great interior distortion is produced. However, with the configuration according to the present invention, the moisture suppression effect was achieved in all tests as described above.

In Experimental Example 3, the edge sealant is provided on the photoelectric conversion layer (CIGS layer), and the number of times the moisture suppression effect was achieved was fewer than in Experimental Examples 1 and 2. Examining the cause of this, it was discovered that there was separation between the photoelectric conversion layer (CIGS layer) and the lower electrodes (Mo film), and that moisture ingressed from the border where the separation occurred.

In Experimental Example 4, the edge sealant is provided on the photoelectric conversion layer (CIGS layer) and the polycarbonate layer is also provided. In Experimental Example 4, the number of times the moisture suppression effect is achieved is fewer than in Experimental Example 3. This is because, as described above, a large interior distortion is produced due to the polycarbonate resin, resulting in separation between the photoelectric conversion layer (CIGS layer) and the lower electrodes (Mo film) in many cases.

What is claimed is:

1. An electronic module comprising:
an electronic device in which an electronic element is provided on a flexible substrate that does not transmit water vapor;
an edge sealant provided at a peripheral edge of the flexible substrate of the electronic device; and
a water vapor barrier film provided so as to cover a region surrounded by the edge sealant;
upon a square root of twice a diffusion coefficient of the edge sealant being K, K being not greater than 0.1 cm/√h; and
the water vapor barrier film comprising a support member made of a transparent resin and at least one inorganic layer formed thereon, and the support member being disposed on a side on which the edge sealant is located.

2. The electronic module according to claim 1, wherein the region surrounded by the edge sealant is filled with a filling material.

3. The electronic module according to claim 1, wherein in the water vapor barrier film, the support member is not greater than 250 μm thick.

4. The electronic module according to claim 2, wherein in the water vapor barrier film, the support member is not greater than 250 μm thick.

5. The electronic module according to claim 1, wherein the edge sealant has a water vapor transmission rate of not greater than 2.0 g/m²/day.

6. The electronic module according to claim 2, wherein the edge sealant has a water vapor transmission rate of not greater than 2.0 g/m²/day.

7. The electronic module according to claim 3, wherein the edge sealant has a water vapor transmission rate of not greater than 2.0 g/m²/day.

8. The electronic module according to claim 4, wherein the edge sealant has a water vapor transmission rate of not greater than 2.0 g/m²/day.

9. The electronic module according to claim 5, wherein the edge sealant contains polyisobutylene.

10. The electronic module according to claim 1, wherein:
the flexible substrate of the electronic device includes one or more metal layers and an insulating layer formed on the one or more metal layers, and the electronic element including lower electrodes and a CIGS film layered together is formed on the insulating layer; and
the edge sealant is provided so as to make contact with a top of the insulating layer or a top of each of the lower electrodes.

11. The electronic module according to claim 2, wherein:
the flexible substrate of the electronic device includes one or more metal layers and an insulating layer formed on the one or more metal layers, and the electronic element including lower electrodes and a CIGS film layered together is formed on the insulating layer; and
the edge sealant is provided so as to make contact with a top of the insulating layer or a top of each of the lower electrodes.

12. The electronic module according to claim 4, wherein:
the flexible substrate of the electronic device includes one or more metal layers and an insulating layer formed on the one or more metal layers, and the electronic element including lower electrodes and a CIGS film layered together is formed on the insulating layer; and
the edge sealant is provided so as to make contact with a top of the insulating layer or a top of each of the lower electrodes.

13. The electronic module according to claim 9, wherein:
the flexible substrate of the electronic device includes one or more metal layers and an insulating layer formed on the one or more metal layers, and the electronic element including lower electrodes and a CIGS film layered together is formed on the insulating layer; and
the edge sealant is provided so as to make contact with a top of the insulating layer or a top of each of the lower electrodes.

14. The electronic module according to claim 1, wherein:
a shock resistant/absorbing layer is provided on the water vapor barrier film and a pressure-resistant layer is provided on a bottom surface of the flexible substrate; and
the shock resistant/absorbing layer and the pressure-resistant layer each comprise polycarbonate resin.

15. The electronic module according to claim 2, wherein:
a shock resistant/absorbing layer is provided on the water vapor barrier film and a pressure-resistant layer is provided on a bottom surface of the flexible substrate; and
the shock resistant/absorbing layer and the pressure-resistant layer each comprise polycarbonate resin.

16. The electronic module according to claim 4, wherein:
a shock resistant/absorbing layer is provided on the water vapor barrier film and a pressure-resistant layer is provided on a bottom surface of the flexible substrate; and
the shock resistant/absorbing layer and the pressure-resistant layer each comprise polycarbonate resin.

17. The electronic module according to claim 9, wherein:
a shock resistant/absorbing layer is provided on the water vapor barrier film and a pressure-resistant layer is provided on a bottom surface of the flexible substrate; and
the shock resistant/absorbing layer and the pressure-resistant layer each comprise polycarbonate resin.

18. The electronic module according to claim 10, wherein:
a shock resistant/absorbing layer is provided on the water vapor barrier film and a pressure-resistant layer is provided on a bottom surface of the flexible substrate; and
the shock resistant/absorbing layer and the pressure-resistant layer each comprise polycarbonate resin.
